(19) United States
(12) Patent Application Publication
(10) Pub. No.: US 2006/0115981 A1
(43) Pub. Date: Jun. 1, 2006

(54) Forming a dual damascene structure without ashing-damaged ultra-low-k intermetal dielectric

(76) Inventors: Jyu-Horng Shieh, Hsin-Chu (TW); Yi-Nien Su, Kaohsiung (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 11/000,793

(22) Filed: Dec. 1, 2004

(51) Int. Cl. H01L 21/4763; H01L 21/31

(52) U.S. Cl. 438/638; 438/778

(57) ABSTRACT

A new method for forming a single or a double damascene interconnect structure is provided in which after the damascene interconnect structure is formed, in which a plasma ashing process is used to remove the photoresist mask used during the photolithography process, the trench-level intermetal dielectric layer is removed leaving gaps between the trench-level interconnect structure. The gaps are then filled with a new layer of ultra-low-k dielectric material providing an ultra-low-k intermetal dielectric layer that has not been damaged by the plasma ashing process.

### FIELD OF THE INVENTION

The present invention relates to a new method of forming a dual damascene interconnect structure in a semiconductor device.

### BACKGROUND

Ultra-low-k (ULK) dielectric materials are often used as intermetal dielectrics (IMD) and interlevel dielectrics (ILD) in damascene interconnect structures to reduce the parasitic capacitance between the metal interconnection features in semiconductor integrated circuits. However, the plasma ashing steps, commonly used in the back-end-of-line (BEOL) processes for removing the photoresist masks created during the photolithography processing, cause undesirable damage to the ULK IMD material.

The damages to the ULK material by the plasma ashing occurs through both carbon depletion and densification that can extend for tens of nanometers into the ULK layer. Carbon depletion occurs when, for example, a Si—CH3 bond in the ULK material is broken and the carbon is replaced with a silicon dangling bond. This results in the formation of silane (Si—OH) through a variety of intermediary reactions and leads to an increase in k value for the damaged portion of the ULK material. In addition the ULK materials are susceptible to kinetic plasma damage that can undesirably densify the ULK material and thus increase its effective k value.

Thus, the susceptibility of ULK materials to plasma ashing-induced damage poses significant manufacturing issues because plasma ashing is common throughout BEOL processes in semiconductor device fabrication.

### SUMMARY

According to an embodiment of the invention, disclosed herein is an improved method for forming a metal interconnect structure in a semiconductor device. The method includes, first forming a damascene structure, wherein the damascene structure includes metal interconnect structures having gaps therebetween and a layer of sacrificial intermetal dielectric (IMD) filling the gaps, the metal interconnect structures being patterned by a photolithography process using a photoresist mask. The photoresist mask is then removed by a plasma ashing process and the metal interconnect structures are planarized by chemical mechanical polishing. The sacrificial IMD layer is removed by plasma etching leaving gaps between the metal interconnect structures. The gaps left behind by the removal of the sacrificial IMD layer is filled with an ultra-low-k (ULK) dielectric material.

The sacrificial IMD layer may be any material that is compatible with the other materials in the semiconductor device, but for the ease of compatibility in a preferred embodiment of the invention, the sacrificial IMD may be a dielectric material and more preferably an ultra-low-k dielectric material. The method of claim 1, wherein the sacrificial IMD layer is removed by plasma etching using at least one of H₂, N₂, NH₃, O₂, He, Ar as plasma etch gas. The plasma etch gas may further include CxHyFz.

The ULK dielectric material can be an oxide based inorganic type or an organic type and the gaps left behind by the removal of the sacrificial IMD layer by either type of ULK dielectric material using a chemical vapor deposition process or a spin-on process.

### BRIEF DESCRIPTION OF THE DRAWINGS

FIGS. 1 through 6B are schematic cross-sectional illustrations of a single damascene structure at various intermediate stages of the damascene process according to an aspect of the invention.

FIGS. 7 through 12B are schematic cross-sectional illustrations of a double damascene structure at various intermediate stages of the damascene process according to another aspect of the invention.

FIG. 13 is a flow chart illustrating the invention.

### DETAILED DESCRIPTION

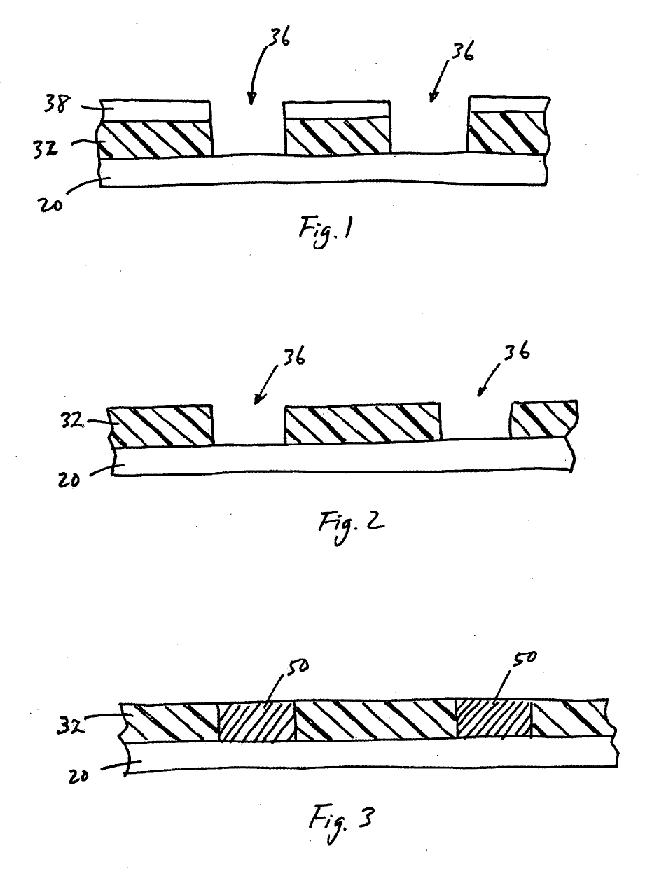

Referring to FIGS. 1 through 6B, a novel process of forming a damascene structure in a semiconductor device according to an embodiment of the invention will be disclosed. FIG. 1 illustrates a cross-sectional view of a damascene structure, in this example a single damascene, in an intermediate stage of the damascene process. In this exemplary intermediate stage, trench openings 36 has been patterned into a ULK dielectric layer 32 by a photolithography processing using a photoresist layer 38 as a mask.

The photoresist layer 38 is then removed by plasma ashing leaving behind a structure shown in FIG. 2. Next, as illustrated in FIG. 3, the trench openings 36 are filled with copper and planarized by chemical mechanical polish (CMP) process to form interconnecting metal conductors 50. At this stage, the ULK IMD layer 32 is typically damaged from the plasma ashing step which was used to remove the photoresist layer 38. Damaged ULK IMD material is not desirable because of its increased dielectric constant.

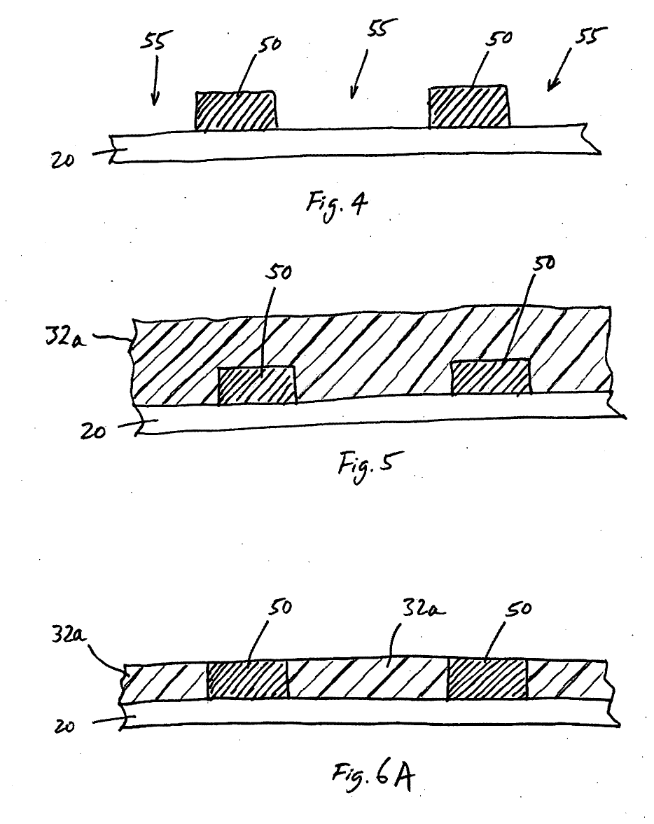

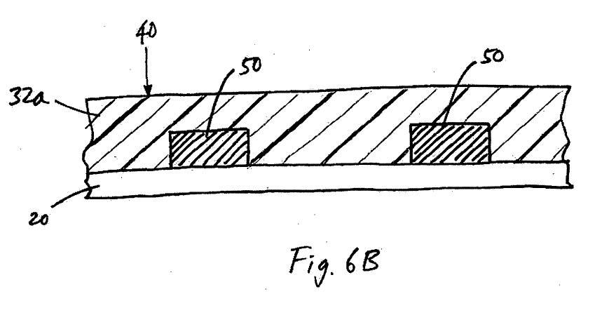

Next, according to an embodiment of the invention, the damaged ULK IMD layer 32 is removed, leaving behind gaps 55 between the interconnecting metal conductors 50 as illustrated in FIG. 4. In other words, the ULK IMD layer 32 is a sacrificial intermetal dielectric layer. The removal of the damaged ULK IMD layer 32 may be accomplished by plasma etch using at least one of Ar, He, H₂, N₂, NH₃, and O₂ as etch gas. The plasma etch gas may also include CxHyFz.

Next, as illustrated in FIG. 5, a new layer of ULK IMD 32a deposited to fill the gaps 55 between the interconnecting metal conductors 50, thus providing a ULK IMD layer whose k value has not been degraded. The ULK dielectric material used for the new ULK IMD layer 32a may be an oxide base inorganic type or organic base type. The new ULK IMD layer 32a may be deposited using a chemical vapor deposition (CVD) process or a spin-on process. Both deposition process options are well known in the art and the details of those processes need not be discussed.

The final thickness of the new ULK IMD layer 32a will be determined by the subsequent processing requirements. If the interconnecting metal conductors 50 is the last interconnect layer, the top surface of the new ULK IMD layer 32a is polished down to the Cu surface of the interconnecting metal conductors 50 and planarized by oxide CMP process. This structure is illustrated in FIG. 6A. If another interconnect layer, such as another single damascene or a dual damascene structures, is to be formed on top of the new ULK IMD layer 32a, the new ULK IMD layer 32a may be oxide CMP polished and planarized down to level 40 necessary to build the next level of ILD layer as illustrated in FIG. 6B.

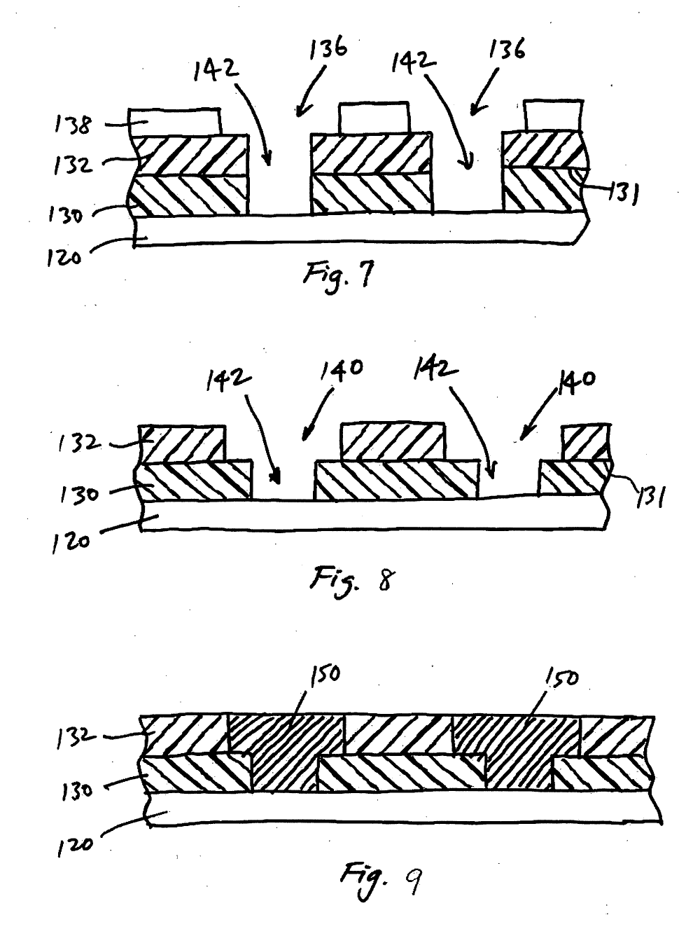

Referring to FIGS. 7 through 12B, a novel process of forming a dual damascene structure in a semiconductor device according to an embodiment of the invention will be disclosed. FIG. 7 illustrates a cross-sectional view of a dual damascene structure in an intermediate stage of the dual damascene process. In this exemplary intermediate stage, via openings 142 is formed in the ULK dielectric layers 130 and 132 following a conventional dual damascene process. Between the two ULK dielectric layers 130 and 132, an etch stop layer 131 of SiN is typically provided. A photoresist layer 138 is deposited over this structure and patterned by a photolithography process using a photoresist mask, forming trench openings 136 and via openings 142.

In the subsequent intermediate structure illustrated in FIG. 8, the conducting line pattern (the trench pattern) 140 is etched into the upper ULK dielectric layer 132, the IMD layer. During the etch process, the etch stop layer 131 prevents the lower ULK dielectric layer 130, the ILD layer, from being etched, thus, maintaining the via openings 142. The photoresist layer 138 has been removed by plasma ashing.

Next, as illustrated in FIG. 9, the via openings 142 and the trench openings 140 are filled with copper and then planarized by CMP process to form interconnecting metal conductors 150 having a dual damascene structure. At this stage, the ULK IMD layer 132 is typically damaged from the plasma ashing step which was used to remove the photoresist layer 138. Damaged ULK IMD material is not desirable because of its increased dielectric constant.

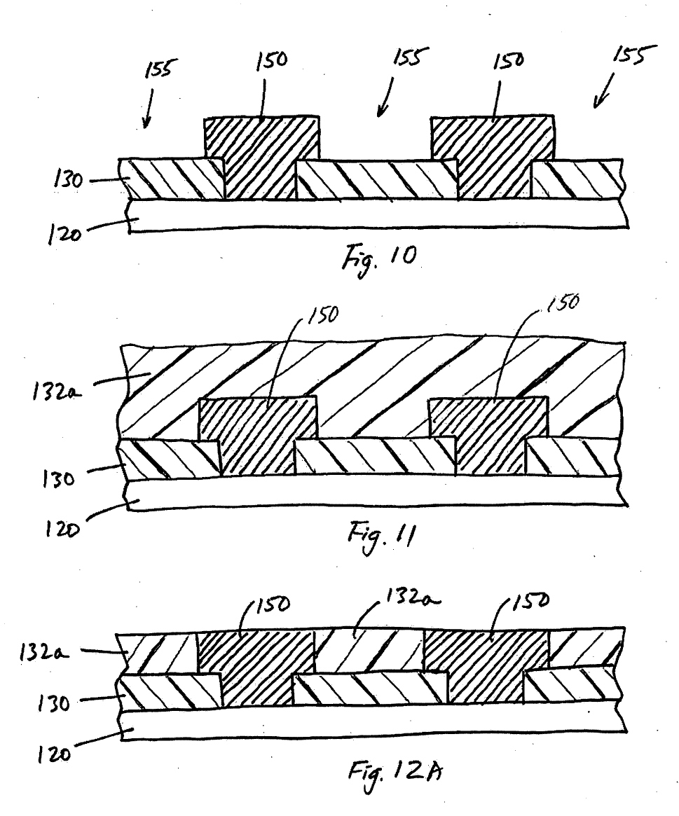

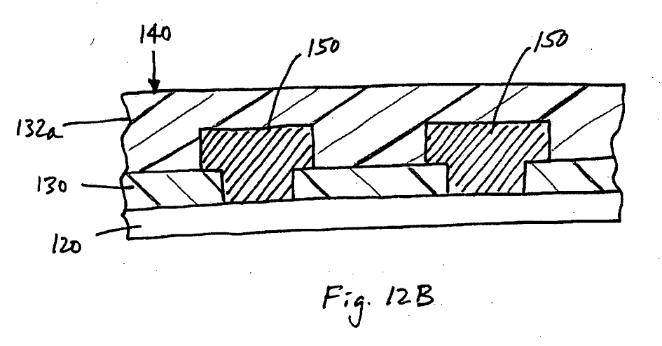

Next, according to the invention, the damaged ULK IMD layer 132 is removed, leaving behind gaps 155 between the interconnecting metal conductors 150 as illustrated in FIG. 10. In other words, the ULK IMD layer 32 is a sacrificial intermetal dielectric layer. The removal of the damaged ULK IMD layer 132 may be accomplished by plasma etch using at least one of Ar, He, H₂, N₂, NH₃, and O₂ as etch gas. The plasma etch gas may also include CxHyFz.

Next, as illustrated in FIG. 11, the gaps 155 between the interconnecting metal conductors 150 are filled by a new layer of ULK IMD layer 132a, thus providing a ULK IMD layer whose k value has not been degraded. The ULK dielectric material used for the new ULK IMD layer 132a may be an oxide base inorganic type or organic base type. The new ULK IMD layer 132a may be deposited using a chemical vapor deposition (CVD) process or a spin-on process. Both deposition process options are well known in the art and the details of those processes need not be discussed.

The final thickness of the new ULK IMD layer 132a will be determined by the subsequent processing requirements. If the interconnecting metal conductors 150 is the last interconnect layer, the top surface of the new ULK IMD layer 132a is polished down to the Cu surface of the interconnecting metal conductors 150 and planarized by oxide CMP process. This structure is illustrated in FIG. 12A. If another interconnect layer, such as another dual damascene or a single damascene structures, is to be formed on top of the new ULK IMD layer 132a, the new ULK IMD layer 132a may be oxide CMP polished and planarized down to the level 140 necessary to build the next level of ILD layer as illustrated in FIG. 12B.

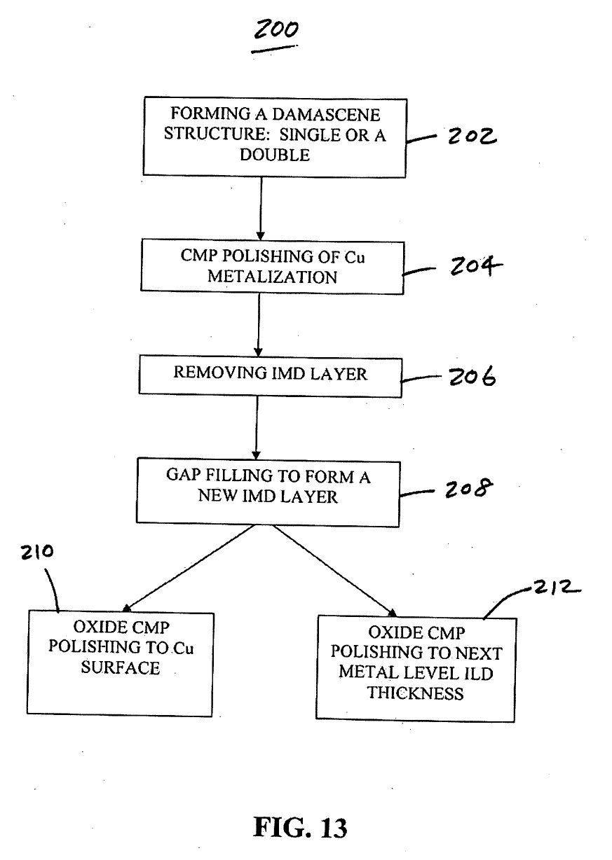

Shown in FIG. 13 is a flow chart 200 illustrating the process steps of the method of the invention described herein. In step 202, a damascene structure is formed. The damascene structure may be a single damascene or a double damascene structure. In step 204, the copper metallization of the damascene structure is CMP polished. In step 206, the IMD layer is removed. The IMD removal step may be accomplished by plasma etching. In step 208, the gaps formed between the copper interconnect metallization by the removal of the IMD layer is filled with a ULK material to form a new ULK IMD layer. This gap filling step may be accomplished by a spin-on process or a CVD process. The ULK material used to form the new ULK IMD layer may be an organic base type or oxide based inorganic type. After the gaps are filled, if no additional interconnect levels are required and a terminal metal layer will be formed above the new ULK IMD layer, in step 210, the new ULK IMD layer is oxide CMP polished down to the Cu interconnecting metal conductors. Alternatively, if additional interconnect levels are to be formed on top of the new ULK IMD layer, in step 212, the new ULK IMD layer is oxide CMP polished down to a level above the copper interconnecting metal conductors so that the new ULK IMD layer forms the next ILD layer.

While the foregoing invention has been described with reference to the above embodiments, various modifications and changes can be made without departing from the spirit of the invention. Accordingly, all such modifications and changes are considered to be within the scope of the appended claims.

1. A method for forming metal interconnect structures in a semiconductor device, the method comprising:
forming a damascene structure, wherein the damascene structure includes metal interconnect structures having gaps therebetween and at least a layer of sacrificial intermetal, ultra-low-k dielectric filling the gaps, wherein the metal interconnect structures are patterned by a photolithograhy process using a photoresist mask;
removing the photoresist mask by a plasma ashing process;
planarizing the metal interconnect structures;
removing the sacrificial intermetal, ultra-low-k dielectric layer, thereby leaving gaps between the metal interconnect structures; and
substantially filling the gaps between the metal interconnect structures with an ultra-low-k dielectric material.

2. (canceled)

3. The method of claim 1, wherein the sacrificial intermetal dielectric layer is removed by plasma etching using at least one of H₂, N₂, NH₃, O₂, He, Ar as plasma etch gas.

4. The method of claim 3, wherein the plasma etch gas further includes CxHyFz.

5. The method of claim 1, wherein the ultra-low-k dielectric material is an oxide based inorganic type and the gaps between the metal interconnect structures are filled by a chemical vapor deposition process.

6. The method of claim 1, wherein the ultra-low-k dielectric material is an oxide based inorganic type and the gaps between the metal interconnect structures are filled by a spin-on process.

7. The method of claim 1, wherein the ultra-low-k dielectric material is an organic type and gaps between the metal interconnect structures are filled by a chemical vapor deposition process.

8. The method of claim 1, wherein the ultra-low-k dielectric material is an organic type and gaps between the metal interconnect structures are filled by a spin-on process.

9. A method for forming an interconnect structure in a semiconductor device, the method comprising:
forming a dual-damascene structure, wherein the dual-damascene structure includes metal interconnect structures having gaps therebetween and at least a layer of sacrificial intermetal, ultra-low-k dielectric filling the gaps, wherein the metal interconnect structures are patterned by a photolithography process using a photoresist mask;
removing the photoresist mask by a plasma ashing process;
planarizing the metal interconnect structure;
removing the sacrificial intermetal, ultra-low-k dielectric layer, thereby leaving gaps between the metal interconnect structures;
substantially filling the gaps between the metal interconnect structures with an ultra-low-k dielectric material.

10. (canceled)

11. The method of claim 9, wherein the sacrificial intermetal dielectric layer is removed by plasma etching using at least one of H₂, N₂, NH₃, O₂, He, Ar as plasma etch gas.

12. The method of claim 11, wherein the plasma etch gas further includes CxHyFz.

13. The method of claim 9, wherein the ultra-low-k dielectric material is an oxide based inorganic type and the gaps between the metal interconnect structures are filled by a chemical vapor deposition process.

14. The method of claim 9, wherein the ultra-low-k dielectric material is an oxide inorganic type and the gaps between the metal interconnect structures are filled by a spin-on process.

15. The method of claim 9, wherein the ultra-low-k dielectric material is an organic type and gaps between the metal interconnect structures are filled by a chemical vapor deposition process.

16. The method of claim 9, wherein the ultra-low-k dielectric material is an organic type and gaps between the metal interconnect structures are filled by a spin-on process.
